(19) United States
(12) Patent Application Publication
(10) Pub. No.: US 2006/0193108 A1
(43) Pub. Date: Aug. 31, 2006

(54) Circuit device and manufacturing method thereof

(75) Inventors: Ryosuke Usui, Ichinomiya-City (JP); Hideki Mizuhara, Ichinomiya-City (JP); Yasunori Inoue, Ogaki-City (JP); Makoto Murai, Mizuho-City (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/359,429

(22) Filed: Feb. 23, 2006

(30) Foreign Application Priority Data
Feb. 28, 2005 (JP) 2005-053742

(51) Int. Cl. H02B 1/00

(52) U.S. Cl. 361/600

(57) ABSTRACT

A thin circuit device that can operate at a high speed is provided. The circuit device includes a first circuit element and a circuit element portion formed on a substrate. The first circuit element and the circuit element portion are arranged in such a manner that element surfaces thereof are opposed to each other. A terminal formed on the element surface of the first circuit element and a terminal formed on the element surface of the circuit element portion are electrically connected to each other via conductive particles in a binder forming an anisotropic conductive film and a via. The anisotropic conductive film and a third insulating resin film are bonded by thermocompression bonding in the same step, thereby simplifying manufacturing steps of the circuit device.

### BACKGROUND OF THE INVENTION

1. Field of the Invention

The present invention relates to a circuit device and a manufacturing method thereof.

2. Description of the Related Art

Portable electronics equipment such as a cell-phone, PDA, DVC, and DSC has become sophisticated at a rapid pace. In order for products of such equipment to be accepted in the marketplace, reduction in size and weight of the product that requires a highly integrated system LSI is necessary.

Moreover, ease of use and convenience are also required for the above electronics equipment. Thus, an LSI used in the above electronics equipment has to be more sophisticated and have higher performance. Therefore, the number of inputs and outputs are increased with increase of the degree of integration in an LSI chip, whereas reduction in the size of a package is strongly demanded. In order to achieve a good balance between the above demands, development of a semiconductor package suitable for high-density mounting of a semiconductor part on a substrate is strongly required.

A structure is known in which circuit devices each including a circuit element mounted thereon are stacked so as to achieve high-density mounting of the circuit elements. A connecting conductor circuit for connecting the circuit elements to each other is formed within an insulating layer (see Japanese Patent Laid-Open Publication No. Hei 7-106509, for example).

However, the above structure has a problem that a wiring connecting the circuit elements to each other is long and therefore a processing speed is low. Moreover, a connection terminal of one circuit element and a connection terminal of another circuit element are connected to each other via a solder electrode or a bump electrode. Thus, the stacked structure of the circuit devices becomes thicker.

### SUMMARY OF THE INVENTION

In view of the foregoing problems, it is therefore an object of the present invention to provide a thin circuit device that can perform a high-speed operation.

According to a first aspect of the present invention, a circuit device comprises a first circuit element and a second circuit element that are arranged in such a manner that an element surface of the first circuit element and an element surface of the second circuit element are opposed to each other, wherein a terminal formed on the element surface of the first circuit element and a terminal formed on the element surface of the second circuit element are electrically connected to each other via a film formed of an insulating resin containing a plurality of conductive particles.

In this structure, the first and second circuit elements are arranged in such a manner that the element surfaces thereof are opposed to each other. Thus, a wiring that connects both the circuit elements to each other can be shortened and therefore a processing speed can be increased. Moreover, since the circuit elements are electrically connected to each other via the film formed of the insulating resin containing the conductive particles, it is possible to manufacture the circuit device in a simpler manner.

The terminal formed on the element surface of the first circuit element and the terminal formed on the element surface of the second circuit element may be electrically connected to each other via an anisotropic conductive film. In this structure, it is possible to manufacture the circuit device in a simpler manner because the anisotropic conductive film can electrically connect the circuit elements to each other.

According to a second aspect of the present invention, a circuit device comprises: a base material; a first circuit element provided on the base material; an insulating layer provided on the first circuit element; a conductive material that is provided in the insulating layer and electrically connects with a terminal formed on an element surface of the first circuit element; a resin layer that is provided on the insulating layer and contains a conductive particle electrically connecting with the conductive material; and a second circuit element that is provided on the resin layer, a terminal formed on an element surface of the second circuit element electrically connecting with the conductive particle.

According to a third aspect of the present invention, a manufacturing method of a circuit device comprises: arranging a first circuit element on a base material; arranging an anisotropic conductive film and a second circuit element on the first circuit element to stack one another; arranging an insulating resin on the second circuit element; and heating the anisotropic conductive film and the insulating resin and pressure-bonding the second circuit element to the anisotropic conductive film and the insulating resin, after the second circuit element is arranged and the insulating resin is arranged.

According to this method, the second circuit element can be simultaneously bonded to both the anisotropic conductive film and the insulating resin by pressure bonding. Therefore, manufacturing steps can be simplified.

The arranging of the second circuit element may comprise arranging the second circuit element with the anisotropic conductive film bonded to its element surface on the first circuit element. Moreover, in the arranging of the second circuit element, the second circuit element may be arranged in such a manner that its element surface is opposed to an element surface of the first circuit element.

### BRIEF DESCRIPTION OF THE DRAWINGS

FIG. 1 is a cross-sectional view of a circuit device according to an embodiment of the present invention;

FIG. 2 is a cross-sectional view showing a manufacturing step of the circuit device of FIG. 1;

FIG. 3 is a cross-sectional view showing a manufacturing step of the circuit device of FIG. 1;

FIG. 4 is a cross-sectional view showing a manufacturing step of the circuit device of FIG. 1;

FIG. 5 is a cross-sectional view showing a manufacturing step of the circuit device of FIG. 1;

FIG. 6 is a cross-sectional view showing a manufacturing step of the circuit device of FIG. 1;

FIG. 7 is a cross-sectional view showing a manufacturing step of the circuit device of FIG. 1;

FIG. 8 is a cross-sectional view showing a manufacturing step of the circuit device of FIG. 1;

FIG. 9 is a cross-sectional view showing a step for arranging a substrate with an ACF according to the embodiment of the present invention;

FIG. 10 is a cross-sectional view showing the step for arranging the substrate with the ACF according to the embodiment of the present invention; and

FIG. 11 is a cross-sectional view showing the step for arranging the substrate with the ACF according to the embodiment of the present invention.

### DETAILED DESCRIPTION OF THE INVENTION

A preferred embodiment of the present invention will be described with reference to the drawings. In the drawings, like parts or elements are denoted by like reference numerals and the description thereof is omitted in an appropriate manner. In the present application, “up” means a notion determined by a forming order of films. That is, with respect to a film formed first, a direction in which a film formed later exists is defined as an upward direction. In this case, it is indifferent whether or not the film formed first is in contact with the film formed later.

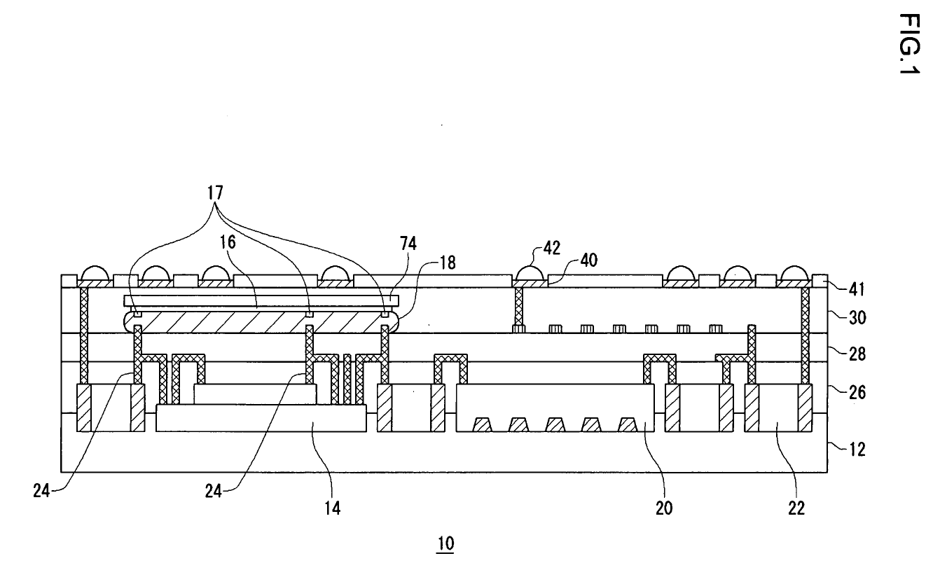

FIG. 1 shows a cross section of a circuit device 10 according to an embodiment of the present invention. The circuit device 10 mainly includes a base material 12, a first circuit element 14, a circuit element portion 16 as a second circuit element that is formed on a substrate 74 such as semiconductor wafer, and an anisotropic conductive film (hereinafter, simply referred to as “ACF”) 18. The circuit device 10 also includes a third circuit element 20, a passive element 22 that is another circuit element, a via 24, a first insulating resin film 26, a second insulating resin film 28, a third insulating resin film 30, a conductive film 40, and a solder electrode 42.

The base material 12 is a plate member on which the first circuit element 14, the third circuit element 20, and another circuit element such as the passive element 22 are fitted into grooves so as to be fixed, respectively. The base material 12 is formed from a cladding material in which a metal having a coefficient of thermal expansion of 0.5×10⁻⁶/K to 5.0×10⁻⁶/K is combined with a metal having thermal conductivity of 200 to 500 W/mK.

Examples of each of the first circuit element 14 and the third circuit element 20 include a transistor, a diode, and an IC chip. The circuit element portion 16 is a circuit element formed on a semiconductor wafer or the like. The first circuit element 14 and the circuit element portion 16 are arranged in the circuit device 10 in such a manner that element surfaces thereof are opposed to each other. Thus, a wiring connecting the first circuit element 14 and the circuit element portion 16 can be shortened. This can make the circuit device 10 thin and can increase a processing speed of the circuit device 10.

The third circuit element 20 has a plurality of concave portions on a rear surface. Each concave portion is filled with a metal. To form the concave portions filled with a metal on the rear surface of the third circuit element 20 can allow heats accumulated in the third circuit element 20 to be easily dissipated to the outside via the metal in the concave portions.

The ACF 18 is a film-like member in which conductive particles are contained in a binder. Examples of the conductive particles include metal particles such as Cu particles, Ag particles, Ni particles, and particles of Ni plated with gold, and particles each containing a core of a resin such as a styrene resin or an acrylic resin plated with gold. Examples of the binder include synthetic rubbers, thermosetting resins, and thermoplastic resins. Typical film thickness of the ACF 18 is about 30 μm.

When two members are pressure-bonded to an upper side and a backside of the ACF 18, those members are electrically connected to each other via the conductive particles. On the other hand, no current flows in a direction along a plane of the film-like ACF 18 because of the binder existing between the conductive particles. In the present embodiment, a predetermined terminal (not shown) on the element surface of the first circuit element 14 and a predetermined terminal 17 on the element surface of the circuit element portion 16 are electrically connected to each other via the ACF 18 and the via 24, as shown in FIG. 1.

The passive element 22 may be a chip capacitor or a chip resistor, for example. The passive element 22 can be formed by embedding a material that forms at least a part of the passive element 22 into a concave portion of the first insulating resin film 26.

The via 24 is formed by embedding a conductive material such as Cu, Al, or a Cu—Al alloy into a via hole by plating or the like. As each of the first, second, and third insulating resin films 26, 28, and 30, a resin that is softened by heating and is then hardened after cooling can be used. Examples of that resin include epoxy resins, melamine derivatives such as BT resins, liquid crystal polymers, PPE resins, polyimide resins, fluorine resins, phenol resins, and polyamidebismaleimide. Those materials can enhance the rigidity of the circuit device 10 and improve the stability of the circuit device 10.

The first, second, and third insulating resin films 26, 28, and 30 fix the circuit element in a stable manner and efficiently dissipate a heat generated in the circuit device. Each of the first, second, and third insulating resin films 26, 28, and 30 may contain a filler or a filling material such as fibers. Examples of the filler include SiO₂ and SiN in the form of particles or fibers.

When each of the first, second, and third insulating resin films 26, 28, and 30 is formed to contain the filling material, it is possible to suppress warpage of that insulating resin film during cooling of that insulating resin film after that insulating resin film is heated and the circuit element is bonded to that insulating resin film by thermocompression bonding. Thermal conductivity can be also increased. Therefore, adhesion between the circuit element and each of the first, second, and third insulating resin films 26, 28, and 30 can be enhanced. Please note that the first, second, and third insulating resin films 26, 28, and 30 are formed of the same insulating resin or different insulating resins from each other.

The conductive film 40 is formed from a rolled metal such as rolled copper, for example. Each of other conductive films 50, 54, 56, and 58 described later can be formed from a rolled metal such as rolled copper. The solder electrode 42 is a backside electrode of the circuit device 10 and is formed by printing solder on the conductive film 40, for example. The circuit device 10 can be electrically connected to an external device such as an external substrate via the solder electrode 42.

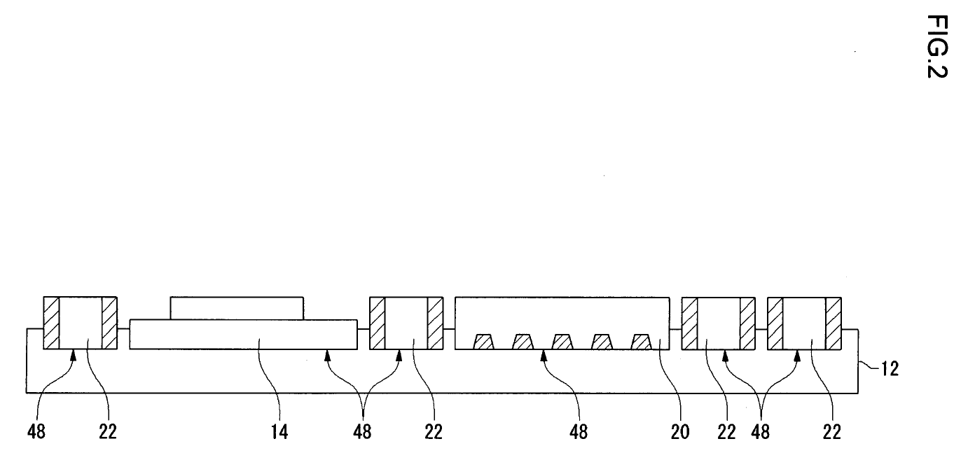

Next, a manufacturing method of the circuit device 10 according to the present embodiment will be described with reference to FIGS. 2 to 8.

FIGS. 2 to 8 are cross-sectional views showing manufacturing steps of the circuit device 10. As shown in FIG. 2, die-chip bonding is performed, which fixes the first circuit element 14, the third circuit element 20, and another circuit element such as the passive element 22 into grooves 48 on the base material 12. In the present embodiment, the grooves 48 are formed in a surface of the base material 12 in regions where the circuit elements are to be mounted. Thus, it is possible to easily and precisely mount the first circuit element 14, the third circuit element 20, and the passive element 22 onto the base material 12 by fitting those elements into the corresponding grooves 48, respectively.

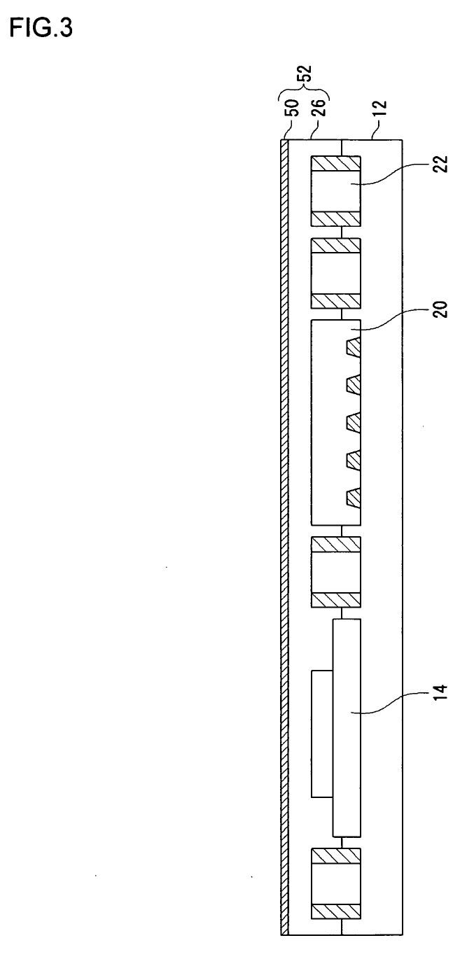

Then, as shown in FIG. 3, a film set 52 of an insulating resin film and a conductive film, which includes a conductive film 50 and the first insulating resin film 26, is bonded to the base material 12. The first circuit element 14, the third circuit element 20, and the passive element 22 are pushed into the first insulating resin film 26 by vacuum pressing. By performing this process, the first circuit element 14, the third circuit element 20, and the passive element 22 are embedded into the first insulating resin film 26 and are pressure-bonded into the first insulating resin film 26 so as to adhere to the first insulating resin film 26. In this process, the first insulating resin film 26 is also bonded to the base material 12.

Even when there is a height difference between the first circuit element 14, the third circuit element 20, and the passive element 22, the insulating resin film gets between the first circuit element 14, the third circuit element 20, and the passive element 22. Thus, the thickness from the base material 12 to the conductive film 40 can be kept uniform. As a result, dimensional accuracy of the circuit device 10 can be improved.

As the film set 52 of the insulating resin film and the conductive film, the first insulating film 26 onto which the conductive film 50 adheres can be used. The film set 52 of the insulating resin film and the conductive film can be formed by applying a resin composition forming the first insulating resin film 26 onto the conductive film 50 and drying the resin composition. In the present embodiment, the resin composition can contain a hardening agent, a hardening accelerator, a viscosity modifier, or another additive within the scope consistent with the object of the present invention.

The film set 52 of the insulating resin film and the conductive film is arranged on the base material 12 in a state in which the first insulating resin film 26 is hardened by primary hardening, partially hardened, or provisionally hardened. This can enhance the adhesion between the first insulating resin film 26 and each of the first circuit element 14, the third circuit element 20, and the passive element 22.

The first insulating resin film 26 is then heated in accordance with the type of the resin forming the first insulating resin film 26, and the film set 52 of the insulating resin film and the conductive film is pressure-bonded to the first circuit element 14, the third circuit element 20, and the passive element 22 under reduced pressure.

Alternatively, the film set 52 of the insulating resin film and the conductive film may be formed by arranging, on the base material 12, the first insulating resin film 26 that is hardened by primary hardening, partially hardened, or provisionally hardened; arranging the conductive film 50 on the first insulating resin film 26; and bonding the conductive film 50 to the first insulating resin film 26 by thermocompression bonding during thermocompression bonding of the first insulating resin film 26 to the first circuit element 14, the third circuit element 20, and the passive element 22.

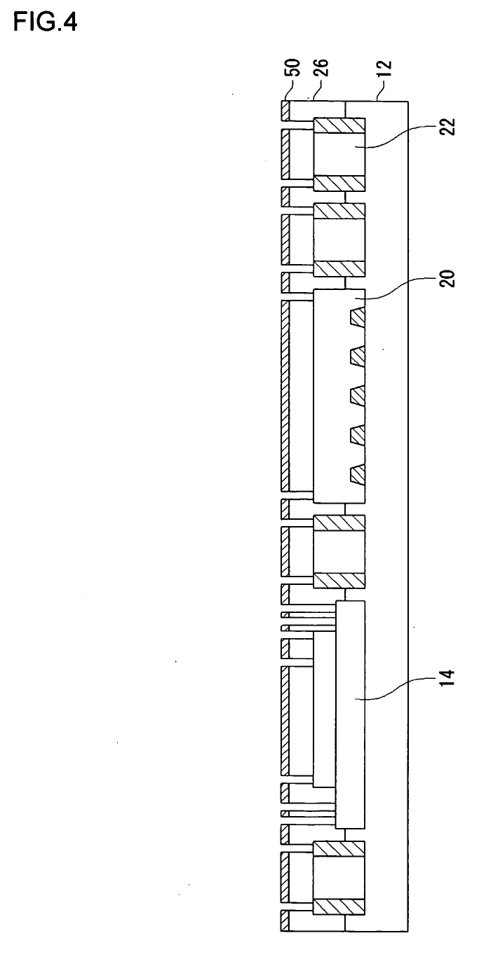

Subsequently, lithography technique known as laser direct imaging is applied to pattern the conductive film 50. Subsequently, the conductive film 50 is subjected to wet Cu etching to form an opening in the Cu film where a via is formed. Then, a via hole is formed in the first insulating resin film 26 by combining irradiation with a carbon dioxide gas laser, irradiation with a YAG laser, and dry etching in an appropriate manner, as shown in FIG. 4.

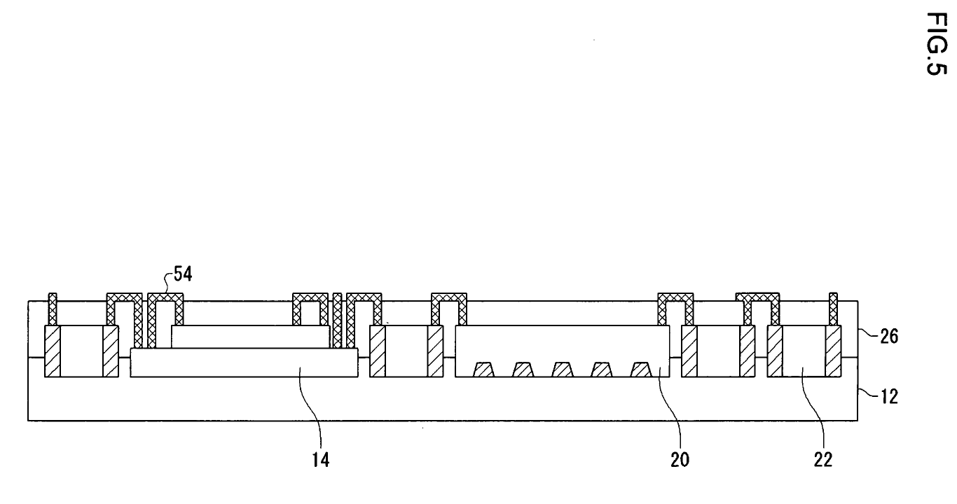

As shown in FIG. 5, Cu is then deposited by electroless Cu plating, sputtering, or the like that corresponds to a high aspect ratio and thereafter a conductive film 54 is formed by electrolytic Cu plating while the via hole is filled with a conductive material. Then, a high-density wiring is formed by patterning using lithography and etching and the first circuit element 14, the third circuit element 20, and the passive element 22 are electrically connected to one another.

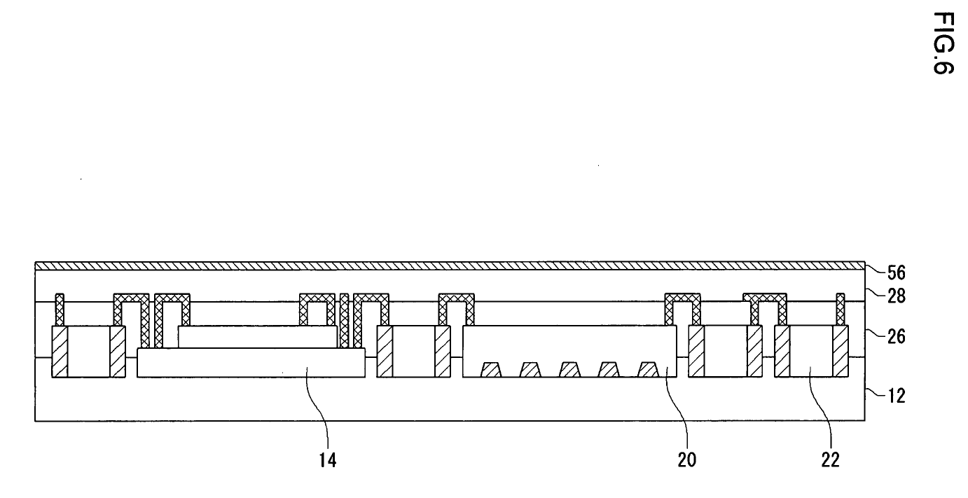

Subsequently, the second insulating resin film 28 with a conductive film 56 is formed, as shown in FIG. 6. In this process, the second insulating resin film 28 is formed on the first insulating resin film 26 and the conductive film 56 is formed on the second insulating resin film 28.

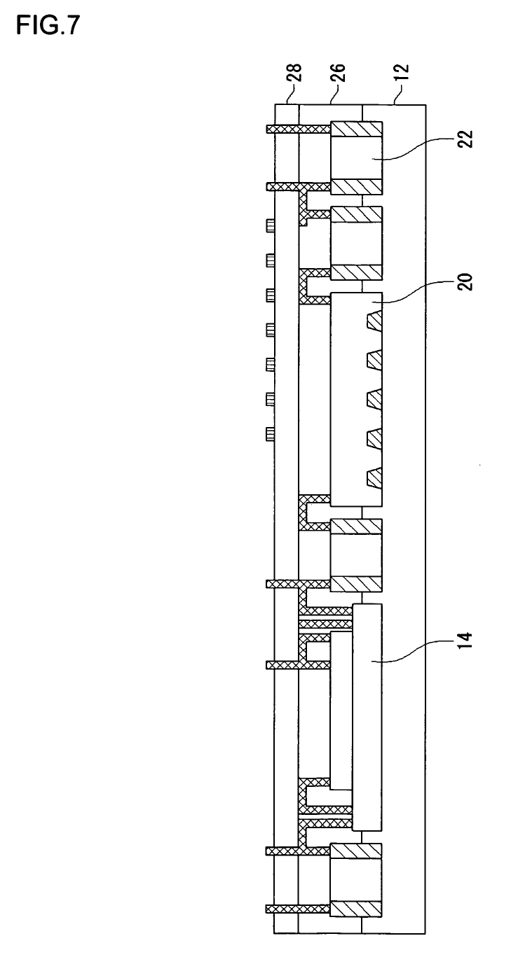

Then, via patterning, via hole forming, plating, and wiring forming that are described above are performed for the second insulating resin film 28 and the conductive film 56 formed thereon in the aforementioned manner, thereby forming a wiring in a second layer, as shown in FIG. 7.

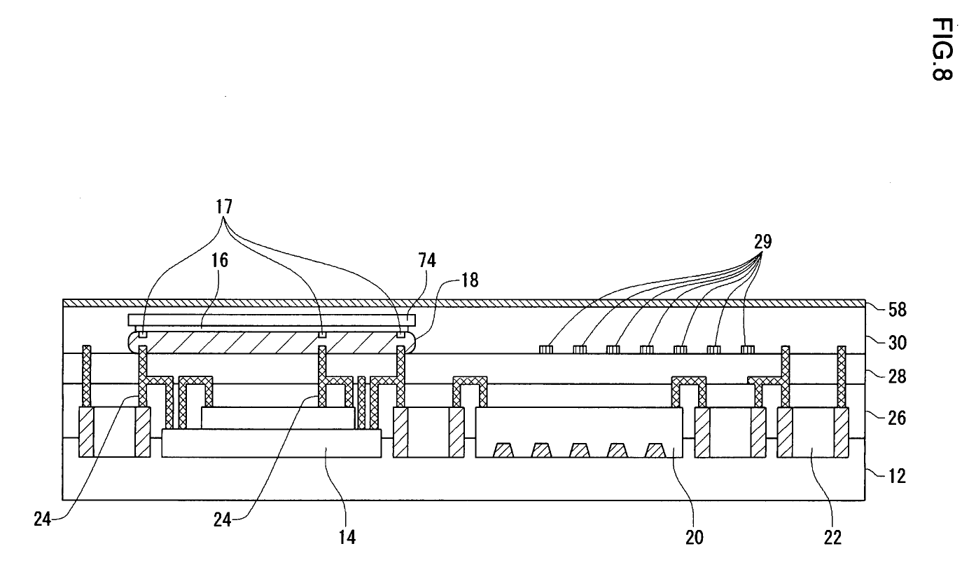

Subsequently, the substrate 74 is arranged in such a manner that the element surface of the circuit element portion 16 is opposed to the element surface of the first circuit element 14 with the ACF 18 interposed therebetween, and the third insulating resin film 30 with a conductive film 58 is arranged on the substrate 74, as shown in FIG. 8. The provision of the ACF 18 on the element surface of the circuit element portion 16 and the arrangement of the circuit element portion 16 with the ACF 18 provided on its element surface on the second insulating resin film 28 will be described later in detail.

Then, the ACF 18 and the third insulating resin film 30 are heated, thereby (1) pressure-bonding the second insulating resin film 28 and the via 24 to the circuit element portion 16 by the ACF 18 and (2) pressure-bonding the third insulating resin film 30 to a wiring 29. In this manner, the ACF 18 and the third insulating resin film 30 are bonded by thermocompression bonding in the same step. Therefore, the manufacturing steps can be simplified.

Subsequently, a wiring in a third layer is formed by performing via patterning, via hole forming, plating, and wiring forming for the third insulating resin film 30 and the conductive film 58 formed thereon in the aforementioned manner. Photo solder resist (PSR) 41 is then deposited and patterned. Then, the solder electrode 42 is formed on the conductive film 40 that is formed on an uppermost surface of the circuit device 10. In this manner, the circuit device 10 shown in FIG. 1 is manufactured.

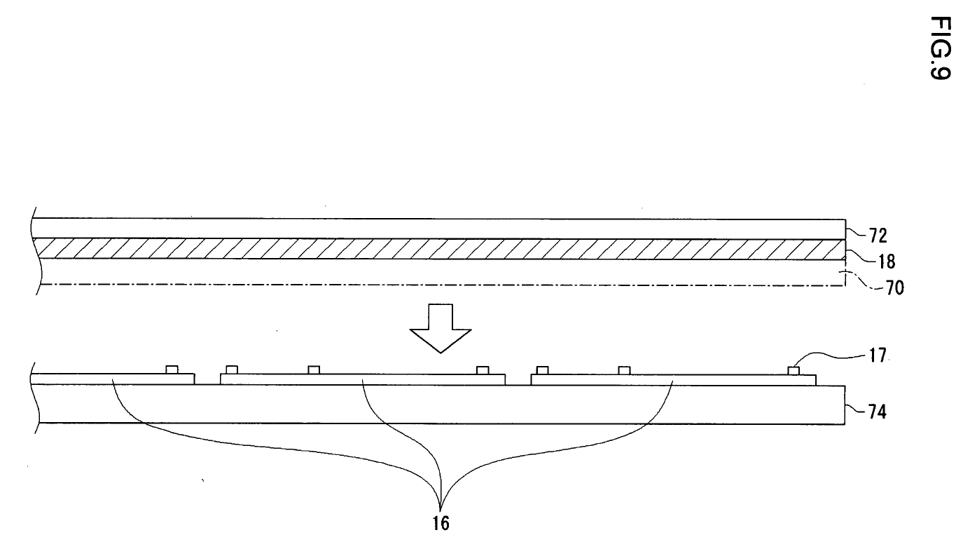

Next, the arrangement of the circuit element portion 16 with the ACF 18 provided on its element surface on the second insulating resin film 28 in the present embodiment will be described in detail with reference to FIGS. 9 to 11.

First, the ACF 18 with release sheets 70 and 72 provided on both sides is prepared. At this time, the binder in the ACF 18 is hardened by primary hardening, partially hardened, or provisionally hardened. Then, the release sheet 70 on one side is removed from the ACF 18 and the ACF 18 is provisionally bonded to a surface of the substrate 74 such as a semiconductor wafer on which the circuit element portion 16 is formed as shown in FIG. 9. Examples of the release sheets 70 and 72 include a PET (PolyEthylene Terephthalate) sheet.

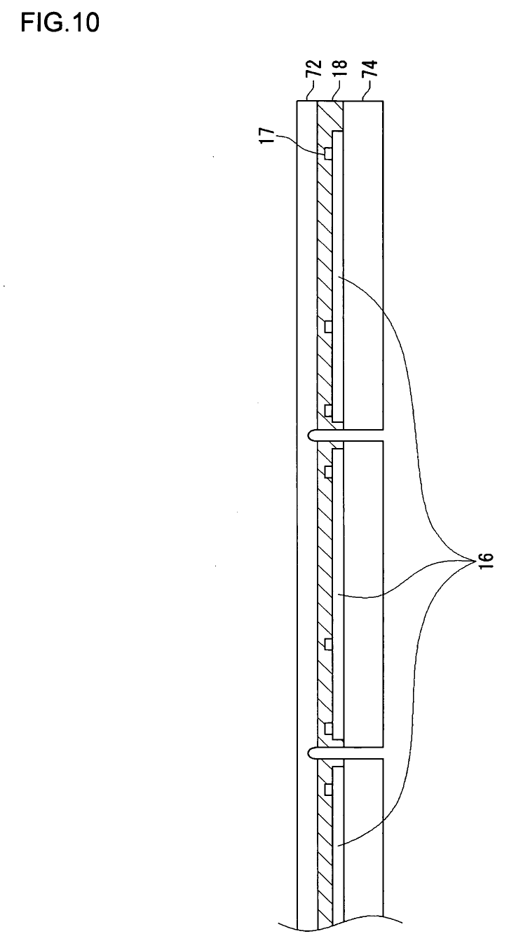

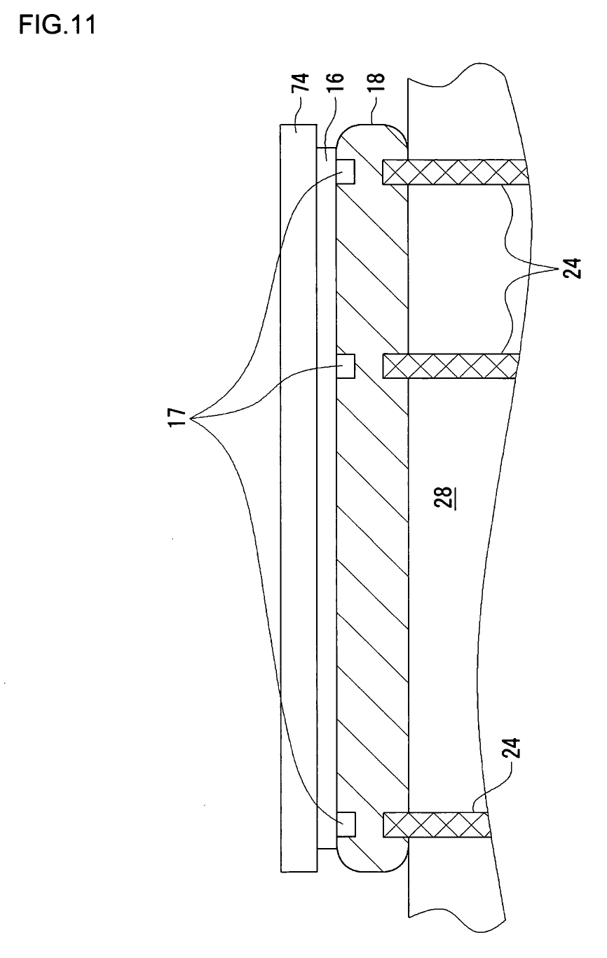

Subsequently, the substrate 74 is diced, as shown in FIG. 10. The dicing is performed in such a manner that the release sheet 72 is partially cut. Then, the substrate 74 on which the ACF 18 is provided on the circuit element portion 16 is separated from the release sheet 72 and is placed on the second insulating resin film 28, as shown in FIG. 11. In this manner, the element surface of the circuit element portion 16 is provisionally arranged to be opposed to the element surface of the first circuit element 14 via the first and second insulating resin films 26 and 28, the via 24, and the ACF 18.

In the above description, the present invention is described based on the preferred embodiment. However, the present invention is not limited thereto. It should be understood that those skilled in the art might make various modifications such as design changes based on their knowledge and embodiments with those modifications could fall within the scope of the present invention.

For example, a method for electrically connecting several layers to one another is not limited to a method that embeds a conductive material into a via hole. The layers may be electrically connected to each other via a wire. In this case, the wire may be coated with a sealing material.

In the circuit device 10 of the present embodiment, a multilayer structure is formed by using an insulating resin film. Alternatively, the multilayer structure may be formed by using a carbon material that can be used for a resistor or a material having a high dielectric constant that can be used for a capacitor.

What is claimed is:

1. A circuit device comprising a first circuit element and a second circuit element that are arranged in such a manner that an element surface of the first circuit element and an element surface of the second circuit element are opposed to each other, wherein
a terminal formed on the element surface of the first circuit element and a terminal formed on the element surface of the second circuit element are electrically connected to each other via a film formed of an insulating resin containing a plurality of conductive particles.

2. The circuit device according to claim 1, wherein
the terminal formed on the element surface of the first circuit element and the terminal formed on the element surface of the second circuit element are electrically connected to each other via an anisotropic conductive film.

3. A circuit device comprising:
a base material;
a first circuit element provided on the base material;
an insulating layer provided on the first circuit element;
a conductive material that is provided in the insulating layer and electrically connects with a terminal formed on an element surface of the first circuit element;
a resin layer that is provided on the insulating layer and contains a conductive particle electrically connecting with the conductive material; and
a second circuit element that is provided on the resin layer, a terminal formed on an element surface of the second circuit element electrically connecting with the conductive particle.

4. The circuit device according to claim 2, wherein
the anisotropic conductive film contains:
a conductive particle selected from the group consisting of a metal particle such as a Cu particle, a Ag particle, a Ni particle, and a particle of Ni plated with gold, and a particle each containing a core of a resin such as a styrene resin or an acrylic resin plated with gold; and
a binder selected from the group consisting of a synthetic rubber, a thermosetting resin, and a thermoplastic resin.

5. The circuit device according to claim according to claim 3, wherein resin layer is an anisotropic conductive film, and
the anisotropic conductive film contains:
a conductive particle selected from the group consisting of a metal particle such as a Cu particle, a Ag particle, a Ni particle, and a particle of Ni plated with gold, and a particle each containing a core of a resin such as a styrene resin or an acrylic resin plated with gold; and
a binder selected from the group consisting of a synthetic rubber, a thermosetting resin, and a thermoplastic resin.

6. A manufacturing method of a circuit device comprising:
arranging a first circuit element on a base material;
arranging an anisotropic conductive film and a second circuit element on the first circuit element to stack one another;
arranging an insulating resin on the second circuit element; and
heating the anisotropic conductive film and the insulating resin and pressure-bonding the second circuit element to the anisotropic conductive film and the insulating resin, after the second circuit element is arranged and the insulating resin is arranged.

7. The manufacturing method of a circuit device according to claim 6, wherein
the arranging of the second circuit element comprises arranging the second circuit element with the anisotropic conductive film bonded to an element surface thereof on the first circuit element.

8. The manufacturing method of a circuit device according to claim 6, wherein
in the arranging of the second circuit element, the second circuit element is arranged in such a manner that an element surface thereof is opposed to an element surface of the first circuit element.

9. The manufacturing method of a circuit device according to claim 7, wherein
in the arranging of the second circuit element, the second circuit element is arranged in such a manner that an element surface thereof is opposed to an element surface of the first circuit element.
